(19) United States
(12) Patent Application Publication
(10) Pub. No.: US 2025/0200234 A1
(43) Pub. Date: Jun. 19, 2025

(54) METHOD AND SYSTEM FOR LOCATING A CENTERLINE IN WALL FRAMES FOR BUILDING LOAD CALCULATION AND WALL FORMATION

(71) Applicant: Consulting Engineers, Corp., Reston, VA (US)

(72) Inventor: Maharaj Jalla, Great Falls, VA (US)

(21) Appl. No.: 18/541,555

(22) Filed: Dec. 15, 2023

Related U.S. Application Data
(63) Continuation-in-part of application No. 16/695,378, filed on Nov. 26, 2019, now abandoned.

(51) Int. Cl. G06F 30/13; G06F 30/12

(52) U.S. Cl. CPC G06F 30/13; G06F 30/12

(57) ABSTRACT

The present invention is a

[symbol]

### CROSS-REFERENCE TO RELATED APPLICATIONS

This application is a continuation-in-part (and claims the benefit of priority under 35 USC 120) of U.S. provisional application No. 62/291,2684 filed Oct. 9, 2019, U.S. provisional application No. 62/912,692 filed Oct. 9, 2019, and U.S. utility application Ser. No. 16/695,378 filed Nov. 26, 2019. The disclosure of the prior applications is considered part of (and is incorporated by reference in) the disclosure of this application.

### BACKGROUND

The disclosure relates generally to building construction and in particular, to a method, computer program, or computer system for identifying the centerline of a wall to perform a load analysis on said wall to develop the framing member layout of the wall while taking into account the overall building design.

The study of architectural drawing has typically been done manually by the user of the software. To study architectural drawings and to identify different elements in the drawings The user has to manually go through all the features of the architectural drawings and manually convert them to the 2D drawings or 3D models. Architectural drawings typically show all the building features which are required for the construction of the building but may not include framing members and may also include non-structural features of the building. They may show the wall finishing material used for the exterior surface and interior surface, doors, furniture, amenities, and the like. It is a tremendous and tedious process to convert this manually to the software format and to convert this accurately. The manual method of inputting the layout of building has disadvantages like time-consuming tasks, lead to an error by incorrect inputs.

However, this process is necessary in any design or detailing software to provide the information and data necessary for the software to effectively perform the calculations. The task of inputting the building features is necessary to calculate accurate engineering design or drawings.

It would be beneficial for there to be software that is able to take drawings and extract the wall centerlines, perform an analysis on the building to determine load requirements, and generate data sets related to the framing member placement and location. The present invention provides for a system and method to convert the content of the architectural drawings to be used for a load analysis, which is then used to determine framing member layouts for the identified wall segments, which can then be converted into 3D models.

### SUMMARY

In a first embodiment, a computer method for calculating the centerline of a wall segment, comprising: receiving, by one or more processors, an architectural drawing of a floor plan, wherein the floor plan includes interior and exterior walls with finishing materials; identifying, by one or more processors, features of the floor plan, wherein the features are physical aspects of wall segments; calculating, by one or more processors, the true width of the wall segments and determining an centerline of the wall segment, wherein the true width is that of framing members; performing, by one or more processors, a load analysis, wherein a strength requirement for each wall segment is determined; generating, by one or more processors, a layout of framing members for each of the wall segments based on the load analysis and the centerline of the wall segments; generating, by one or more processors, layers of the framing member layout and the centerline layout of the floor plan.

In a second embodiment, a computer program product for locating the centerline of a frame member, the computer program product comprising a non-transitory computer readable storage medium having program instructions embodied therewith, the program instructions executable by a computing device to cause the computing device to: program instructions to receive a set of floor plans that comprise a building design; program instructions to identify features of the floor plan, wherein the features are the wall segments and apertures; program instructions to isolate the wall segments of the floor plans, wherein a wall segment layer is created; program instructions to calculate a true width of the wall segments, wherein the true width is that of framing members; program instructions to generate a layer of the floor plans depicting a centerline of the true width of the wall segments; program instructions to perform a load analysis on the floor plans while taking into consideration the building design to identify structural requirements for each wall segment; program instructions to generate a framing member layout based on the structural requirements of the wall segments; and program instructions to generate a layer of the framing member layout.

In a third embodiment, a system comprising: a CPU, a computer readable memory and a non-transitory computer readable storage medium associated with a computing device; program instructions to receive a set of floor plans, wherein the set of floor plans comprise a building; program instructions to generate a building model from the set of floor plans and determine a load for the building model; program instructions to identify wall segments of each of the set of floor plans and determine finishing materials which are part of the wall segment thickness; program instructions to calculate a true width of the wall segments, wherein the true width is of the framing members; program instructions to generate a layer, wherein the layer is of a centerline of the true width of the wall segments; program instructions to perform a load analysis on the building, wherein a strength requirement for each wall segment is calculated; and program instructions to generate a layout of framing members for each wall segment.

### BRIEF DESCRIPTION OF THE DRAWINGS

FIG. 1 depicts a block diagram depicting a computing environment, in accordance with one embodiment of the present invention.

FIG. 2 depicts a block diagram depicting the internal and external components of the server and computing device of FIG. 1, in accordance with one embodiment of the present.

FIG. 3 depicts a cloud computing environment, in accordance with one embodiment of the present invention.

FIG. 4 depicts a flowchart of the operational steps of a method for calculating and generating the sheathing requirements for the construction of a building within the computing environment of FIG. 1, in accordance with one embodiment of the present invention.

FIG. 5 depicts a user interface for identifying the building floor designs, in accordance with one embodiment of the present invention.

FIG. 6, depicts an “L” junction of two walls, in accordance with one embodiment of the present invention.

FIG. 7, depicts a “T” junction of two walls, in accordance with one embodiment of the present invention.

FIG. 8, depicts a user interface showing a unit of a building assembly, in accordance with one embodiment of the present invention.

FIG. 9, depicts a user interface showing the unit of a building as a centerline drawing, in accordance with one embodiment of the present invention.

FIG. 10, depicts a user interface showing the unit of a building as framing members, in accordance with one embodiment of the present invention.

### DETAILED DESCRIPTION

The present invention provides a process of analyzing architectural drawing or floor models of a building to determine the centerline of the walls and wall segments so that a load analysis can be performed to determine the framing member design and layout of the wall segments based on the overall building load. This analysis provides many advantages both in terms of efficiency but also extracting data from drawings which would normally have to be manually extracted and performing an analysis on the walls to determine framing member layout data which was previously unknown and is used for the generation of new novel drawings and model files.

Typically, the task of inputting walls into a building model, which are based on architectural drawings is manually performed and is a requirement to calculate accurate engineering design reports. This manual entry also has many issues in terms of accuracy and each individual wall which is manually input, but also the overall building design is prone to errors which will negatively affect the load calculations to determine the wall frame member quantity and layout The present invention provides an approach to convert drawings of a building to centerlines of the wall segments that is an accurate representation of the building. Using this centerline drawing to perform a load analysis so that the frame members for each wall segment can be determined, and drawings and/or 3D models can be created showing the framing member layout. This data is stored, and when the design or detailing software is to be implemented, the present invention is able to use the centerline data to automatically generate the building or structure layout to the design or detailing software format.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowcharts and block diagrams in the Figures illustrate the architecture, functionality, and operation of possible implementations of systems, methods, and computer program products according to various embodiments of the present invention. In this regard, each block in the flowcharts may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the flowchart illustrations, and combinations of blocks in the flowchart illustrations, can be implemented by special purpose hardware-based systems that perform the specified functions or acts or carry out combinations of special purpose hardware and computer instructions.

It is understood in advance that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

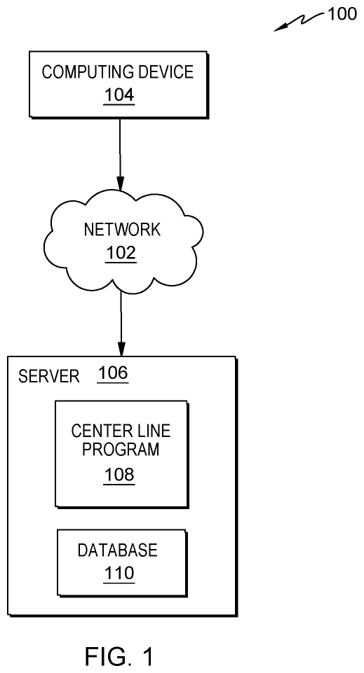

FIG. 1 depicts a block diagram of a computing environment 100 in accordance with one embodiment of the present invention. FIG. 1 provides an illustration of one embodiment and does not imply any limitations regarding the environment in which different embodiments may be implemented.

In the depicted embodiment, computing environment 100 includes network 102, computing device 104, and server 106. Computing environment 100 may include additional servers, computers, or other devices not shown.

Network 102 may be a local area network (LAN), a wide area network (WAN) such as the Internet, any combination thereof, or any combination of connections and protocols that can support communications between computing device 104 and server 106 in accordance with embodiments of the invention. Network 102 may include wired, wireless, or fiber optic connections.

Computing device 104 may be a management server, a web server, or any other electronic device or computing system capable of processing program instructions and receiving and sending data. In other embodiments, computing device 104 may be a laptop computer, tablet computer, netbook computer, personal computer (PC), a desktop computer, or any programmable electronic device capable of communicating with patient computing device 104 via network 102. In other embodiments, computing device 104 may be a server computing system utilizing multiple computers as a server system, such as in a cloud computing environment. In one embodiment, computing device 104 represents a computing system utilizing clustered computers and components to act as a single pool of seamless resources. Computing device 104 may include components, as depicted and described in further detail with respect to FIG. 1.

Server 106 may be a management server, a web server, or any other electronic device or computing system capable of processing program instructions and receiving and sending data. In other embodiments server 106 may be a laptop computer, tablet computer, netbook computer, personal computer (PC), a desktop computer, or any programmable electronic device capable of communicating via network 102. In one embodiment, server 106 may be a server computing system utilizing multiple computers as a server system, such as in a cloud computing environment. In one embodiment, server 106 represents a computing system utilizing clustered computers and components to act as a single pool of seamless resources. In the depicted embodiment Centerline Program 108 and database 110 are located on server 106. Server 106 may include components, as depicted and described in further detail with respect to FIG. 1.

Centerline Program 108 has the unique and novel features of being able to take a model or drawing of a floor plan or an architectural drawing and determine the centerline of the wall(s) and wall segments and generate specific data related to these centerlines. The centerline data is then used in a load analysis of the building to determine the minimum strength requirements for each wall and wall segment. The Centerline Program 108 then determine a layout of the framing members that are required to build each wall and wall segment and create a novel set of drawings or a 3D model of the framing members based on the identified centerline of each wall segment. The Centerline Program 108 is able to create drawings and models of the walls and framing members. This data is able to be converted into a data type accepted by various design or detailing software. In the depicted embodiment, Centerline Program 108 utilizes network 102 to access the computing device 104 and to communicate with database 110. In one embodiment, Centerline Program 108 resides on computing device 104. In other embodiments, Centerline Program 108 may be located on another server or computing device, provided Centerline Program 108 has access to database 110.

Database 110 may be a repository that may be written to and/or read by Centerline Program 108. Information gathered from computing device 104 and the 1-dimensional, 2-dimensional, and 3-dimensional drawings and models as well as the requirements so that the materials and members are identified as conflicting or non-conflicting. In one embodiment, database 110 is a database management system (DBMS) used to allow the definition, creation, querying, update, and administration of a database(s). In the depicted embodiment, database 110 resides on computing device 104. In other embodiments, database 110 resides on another server, or another computing device, provided that database 110 is accessible to Centerline Program 108.

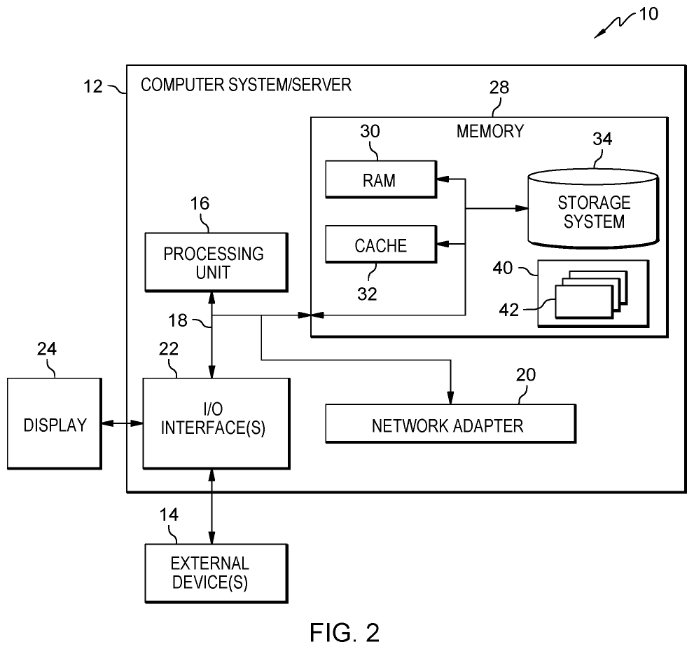

FIG. 2, a schematic of an example of a computing node is shown. computing node 10 is only one example of a suitable computing node and is not intended to suggest any limitation as to the scope of use or functionality of embodiments of the invention described herein. Regardless, computing node 10 is capable of being implemented and/or performing any of the functionality set forth hereinabove.

In computing node 10 there is a computer system/server 12, which is operational with numerous other general purposes or special purpose computing system environments or configurations. Examples of well-known computing systems, environments, and/or configurations that may be suitable for use with computer system/server 12 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed computing environments that include any of the above systems or devices, and the like.

Computer system/server 12 may be described in the general context of computer system executable instructions, such as program modules, being executed by a computer system. Generally, program modules may include routines, programs, objects, components, logic, data structures, and so on that perform particular tasks or implement particular abstract data types. Computer system/server 12 may be practiced in distributed computing environments where tasks are performed by remote processing devices that are linked through a communications network. In a distributed computing environment, program modules may be located in both local and remote computer system storage media including memory storage devices.

Computer system/server 12 in computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random-access memory (RAM) 30 and/or cache memory 32. Computer system/server 12 may further include other removable/non-removable, volatile/non-volatile computer system storage media. By way of example only, storage system 34 can be provided for reading from and writing to a nonremovable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples include, but are not limited to microcode, device drivers, redundant processing units, external disk drive arrays, RAID systems, tape drives, and data archival storage systems, etc.

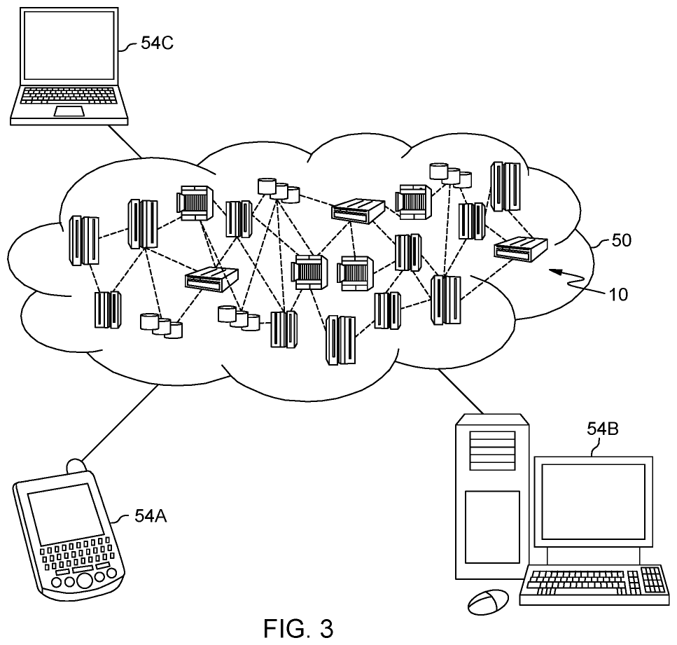

FIG. 3, illustrative cloud computing environment 50 is depicted. As shown, cloud computing environment 50 comprises one or more computing nodes 10 with which local computing devices used by cloud consumers, such as, for example, personal digital assistant (PDA) or cellular telephone 54A, desktop computer 54B, laptop computer 54C, and/or additional computer systems may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-C shown in FIG. 2 are intended to be illustrative only and that computing nodes 10 and cloud computing environment 50 can communicate with any type of computerized device over any type of network and/or network addressable connection (e.g., using a web browser).

Referring back to FIG. 2, the Program/utility 40 may include one or more program modules 42 that generally carry out the functions and/or methodologies of embodiments of the invention as described herein. Specifically, the program modules 42 may monitor real-time parking facility camera data, receive vehicle identification information for a vehicle entering a parking facility, identify driver and vehicle information based on the vehicle identification information, identify open parking spaces based on the real-time parking facility camera data, determining attributes of the open parking spaces, score the open parking spaces based on the attributes, the vehicle information, and the driver information, select a particular open parking space based on the scoring, determine navigation directions to the selected parking space, and outputting navigation directions and information for the selected parking space, e.g., to a user device of the driver and/or to a vehicle interface system, such as a vehicle navigation system. Other functionalities of the program module 42 are described further herein such that the program modules 42 are not limited to the functions described above. Moreover, it is noted that some of the modules 42 can be implemented within the infrastructure shown in FIGS. 1-3.

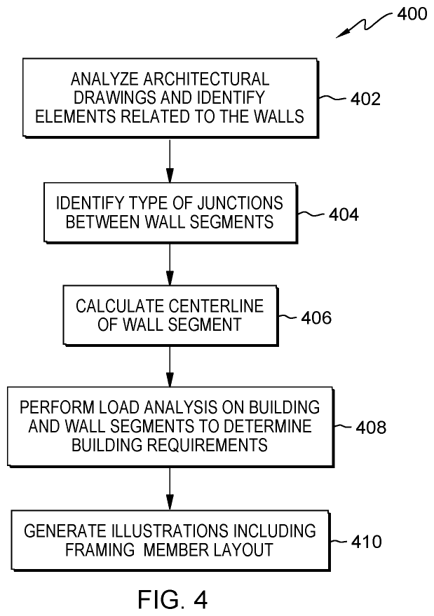

FIG. 4 depicts flowchart 400 depicting a method according to the present invention. The method(s) and associated process(es) are now discussed, over the course of the following paragraphs, in accordance with one embodiment of the present invention. The program(s) described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

In step 402, the Centerline Program 108 analyzes architectural drawings to identify elements related to wall segments of the building. The Centerline Program 108 is able to determine the unique features of the architectural drawings, building drawings, or models which are then used to locate the centerlines for all of the walls, both interior and exterior walls. Typically, the exterior or primary walls have many layers of protective material (e.g. siding) which adds to the overall thickness of the wall but is not needed when calculating the true thickness of the wall for the purpose of identifying the centerline of the wall. Interior walls may also have various layers which are not needed for the calculation of the centerline and thus the Centerline Program 108 is able to remove these unnecessary features or aspects of the walls for the centerline calculation.

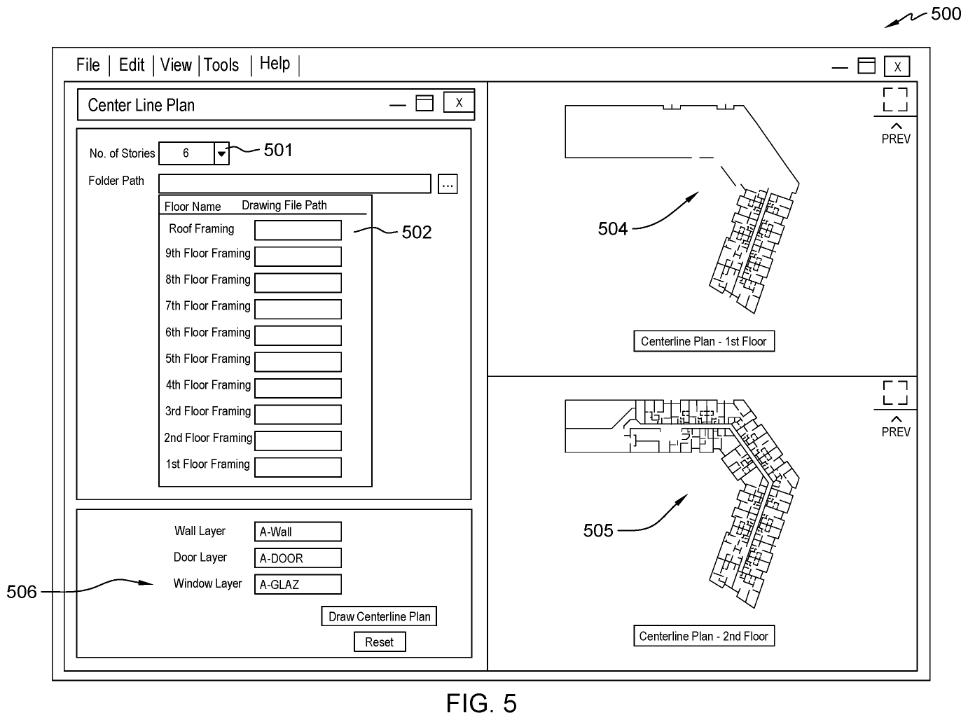

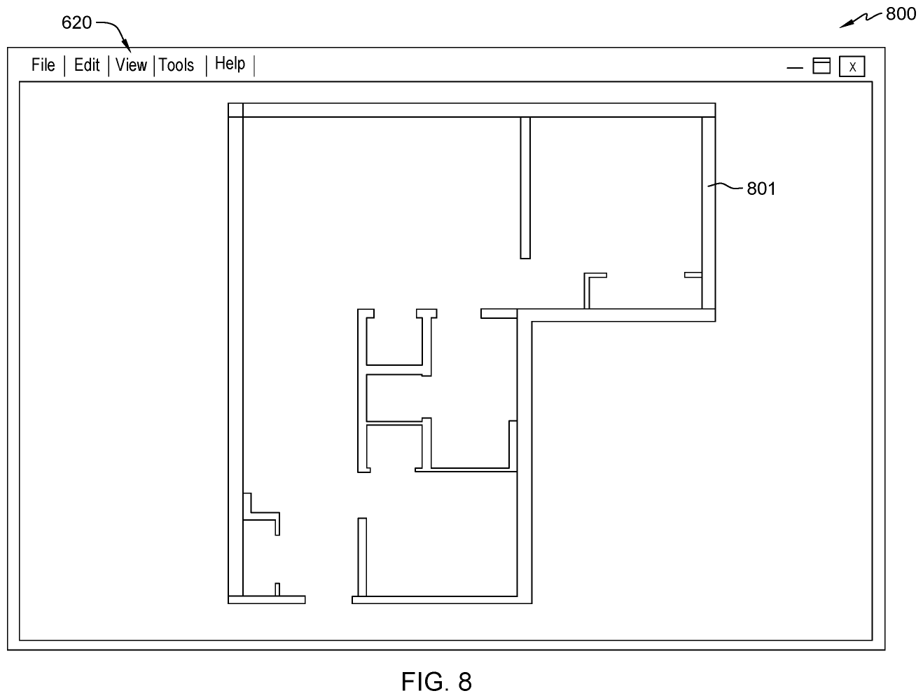

FIG. 5 depicted an illustration 500 of a user interface showing where the user is able to input the drawing or file path 502 for each floor of the building, as well as the inputs the user needs to select when uploading the files. The user selects the number of floors 501 which affects the input list 502. The user also selects the wall, door, window 503 and other layers for the program to use in the calculation of the centerline analysis. Also shown is an image of each floor that is uploaded 504 and 505. In the depicted embodiment, the first 504 and second 505 floors are shown but multiple floors can be shown based on the number of floors selected and uploaded. FIG. 8 depicts a view of a unit 800 within a floor drawing, wherein unit 800 is shown in greater detail for exemplary purposes. The unit 800 view extracted from the larger floor plan view as the Centerline Program 108 is able to isolate one or more of the units within the floor plan. This illustration is for exemplary purposes and does not limit the Centerline Program 108 ability to view specific portions of a floor plan. In the depicted illustration, walls 801 are shown without any additional features or elements.

In additional embodiments, Centerline Program 108 is able to analyze the wall segments and determine the location of any aperture (e.g., window, doorway, or the like) in the floor plan. The aperture provided for the Centerline Program 108 to determine the wall segments versus the overall wall size. This assists with the removal of features of the drawing which are not included in the identification of the walls as the program is able to methodically scan each line in the drawings and determine the placement and purpose of that line and if it is related to a wall segment or not. The apertures are analyzed and the width of the opening is identified. In typical building construction techniques, some sheathing material along the edges of the opening are shown. It means the opening width shown in the drawing and the opening width required in the structural framing material are not the same. The correct opening width including the tolerances are required to keep the true dimensions of the floor intact.

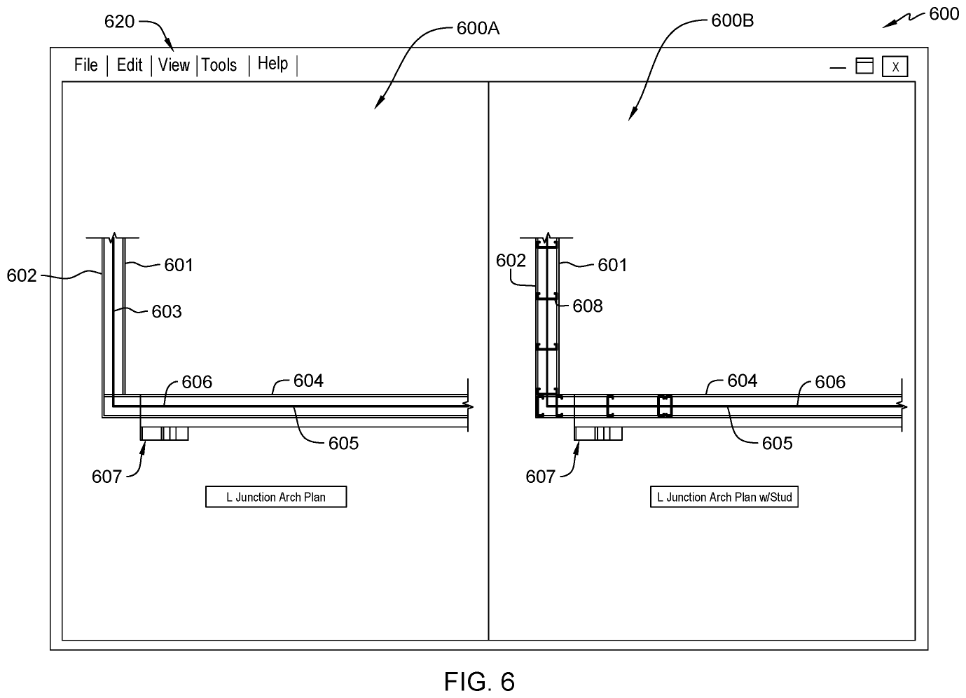

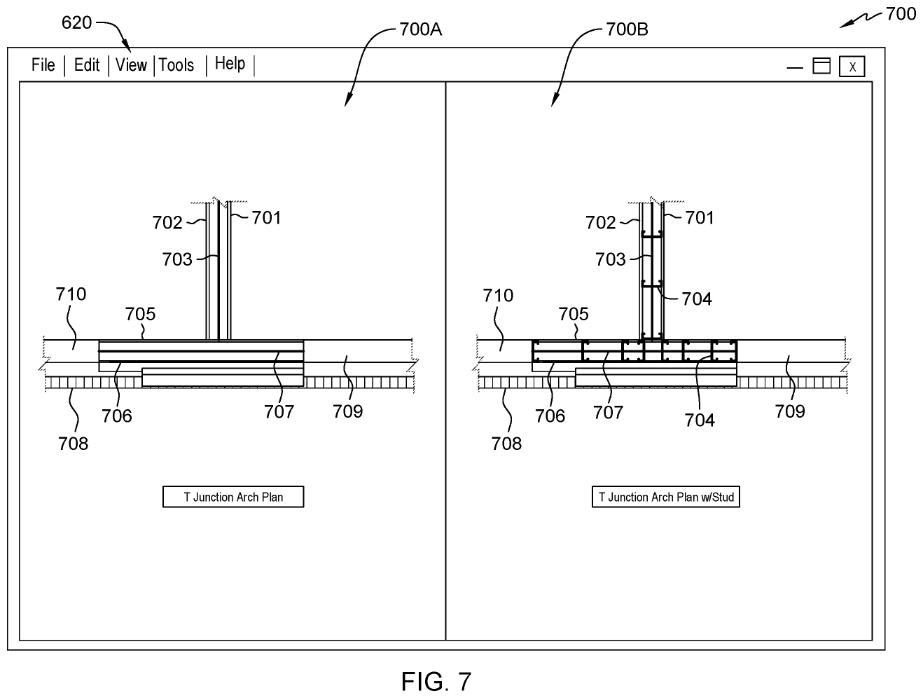

In step 404, the Centerline Program 108, identifies the type of junction between the wall segments. The type of junction is important to understand where the true centerline of the wall segments would be and also for the load analysis to determine the placement of the framing members. Once the Centerline Program 108 is able to identify the walls and the individual wall segments, the Centerline Program 108 identifies the junction type between interfacing walls and wall segments. The parts of the building which are known have a set of material properties applied to each part so that the load analysis is able to accurately determine the overall load on the building. For example if parts are made from concrete, glass, metal, wood, etc. Each material type has a set of real life properties associated with that material for the load analysis. This analysis identifies where two or more walls interface and determines where each wall ends based on common building practices and know construction techniques and is able to identify these interfaces to maintain the wall segments. FIG. 6 depicts an L junction 600 and FIG. 7 depicts a T junction 700 (respectively) between two wall segments. These figures show sections of the overall walls as the user has the ability to focus the viewable space of the walls or junctions based on the user's desires. In some embodiments, multiple entire floor plans can be visible or sections of the floor plans that show multiples junctions. The depicted embodiments are for exemplary purposes and do not limit the ability of the user to select various sections of the floor plans. The two views shown in the user interface are identical sections of the building floor plan and both views will update as the user adjusts the viewable section of the floor plan. The user has the ability to adjust what elements are shown in the two views, as the depicted embodiments show one view of the junction without framing members and one view of the junction with framing members including various features of each wall. These two types of junctions are the most common but not a complete list of all possible wall segment junctions. In these two depictions of the building, the walls are shown with the finishing materials on the exterior and the interior surfaces of the walls. The framing members which are not present need to be calculated and identified based on the determined center of the wall. The Centerline Program 108 creates a plurality of data points to determine the width of the wall, the thickness of the finishing materials or sheathing materials which are applied to the wall (e.g., drywall, stucco, brick, shingles, etc.).

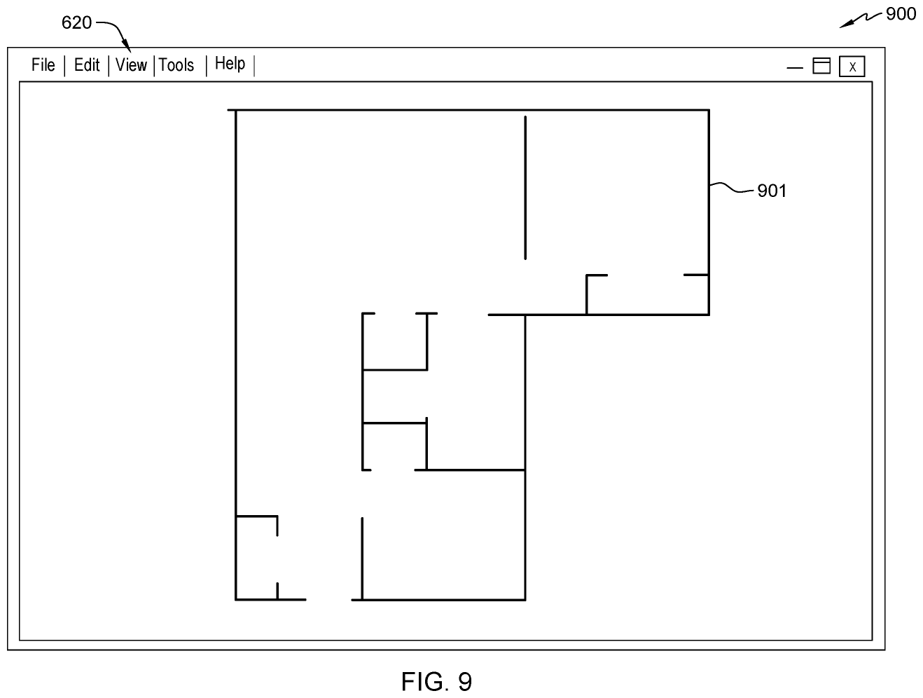

In step 406, the Centerline Program 108 calculates the centerline of the wall segments given the identification of the features of the walls and wall segments and the identified junction types between the wall segments. The Centerline Program 108 takes the identified exterior edges of the true wall and calculates a centerline from these known values. From the total wall width in the drawings, the Centerline Program 108 is able to determine the true wall dimensions by analyzing the walls and determining the true with, the centerline of the wall is calculated. After the calculation of the centerline of the wall segments, the Centerline Program 108 generates a layer depicting the centerline. An example is shown in FIG. 9, where user interface 900 shows an image of the centerlines 901 of each wall segment. This newly generated layer of the centerline is stored and can be overlayed on other layers, for example as shown in illustrations 600 and 700. FIG. 9 depicts the single unit as an example, but the Centerline Program is able to perform this calculation for the entire floor of the building and creates the centerline layer for the entire floor and each of the floors of the entire building. This view of the centerlines 901 shows the true center of each of the wall segments. In some embodiments, doors and windows are also identified, as these features are used to assist the Centerline Program 108 with determining the wall segments and the doors and windows are depicted in visually distinguishable ways.

These illustrations show the true length of each wall segment and are necessary for the calculation to determine the placement of the frame members based on the load analysis. In some embodiments, these illustrations are created on a separate layer from the drawings. As shown in Figure 600A, an L junction between two wall segments is shown having an interior edge 601 and 604 and an exterior edge 602 and 605 of the respective wall segments. The true centerline is lines 603 and 606 of the respective wall segments, which takes into account all the additional materials 607 which is part of the wall segment, but not relevant to the centerline calculation which is used for the framing members. Figure 700A depicts a T junction showing the edges 701 and 702 of a wall segment and edges 705 and 706 of a second wall segment, as well as the centerlines 703 and 707 of the respective wall segments. The centerlines are calculated based on the wall edges and not the overall wall thickness. As shown the second wall segment has portion 708 which increases the wall thickness but is not relevant to the calculation for centerline 707. In the depicted illustrations, sections 709 and 710 show an aperture of the wall segment, where the centerline 707 does not extend into or through. In instances where the aperture is a window, the centerline may extend through the window section due to framing members being present below and above the window aperture, if it does not extend from ceiling to floor.

This unique way of creating multiple layers for each aspect of the building, allows the Centerline Program 108 to convert these layers into new illustrations of the floors of the building for the creation of a 3D model for the creation of new 2D drawings. With the original drawings, the centerline drawings, and the framing member drawing. The Centerline Program 108 The unique way of importing the centerlines of the wall segments to develop the wall layout in the design software has several advantages over conventional methods. One main advantage is the perfect replication of the floor plan and wall placement to completely remove the potential for errors when transferring the floor plan because of the miscalculation of finishing or sheathing material being incorporated into the structural measurements.

In step 408, the Centerline Program 108 applies a load analysis on the building to determine a set of building requirements for the overall building, including a set of building requirements for each of the wall segments. The set of building requirements can be adjusted by the user, but the Centerline Program 108 has a default minimum set of building requirements to maintain a safe building design. The load(s) are applied on each wall segment to imitate a real-world environment so that strength requirements for the wall segments can be determined. Based on these strength requirements, the Centerline Program 108 is able to determine a framing member layout for each wall segment based on known framing member properties and the wall segment minimum strength requirements. Based on the data entered in FIG. 5, the Centerline Program 108 is able to perform a load analysis on the entire building to determine the framing member layout and design for each wall segment. The load analysis takes into account all known structural elements of the building to determine the required strength of all the structural elements. The load(s) are applied to imitate a real-world scenario of the building design taking into account materials and structural properties of the materials. The Centerline Program 108 may perform the analysis on each individual wall segment or may perform the analysis on the entire building at once. The loads are applied based on the building design, and a real-world environment on the walls or wall segments being load bearing or non-load bearing, interior, and exterior walls.

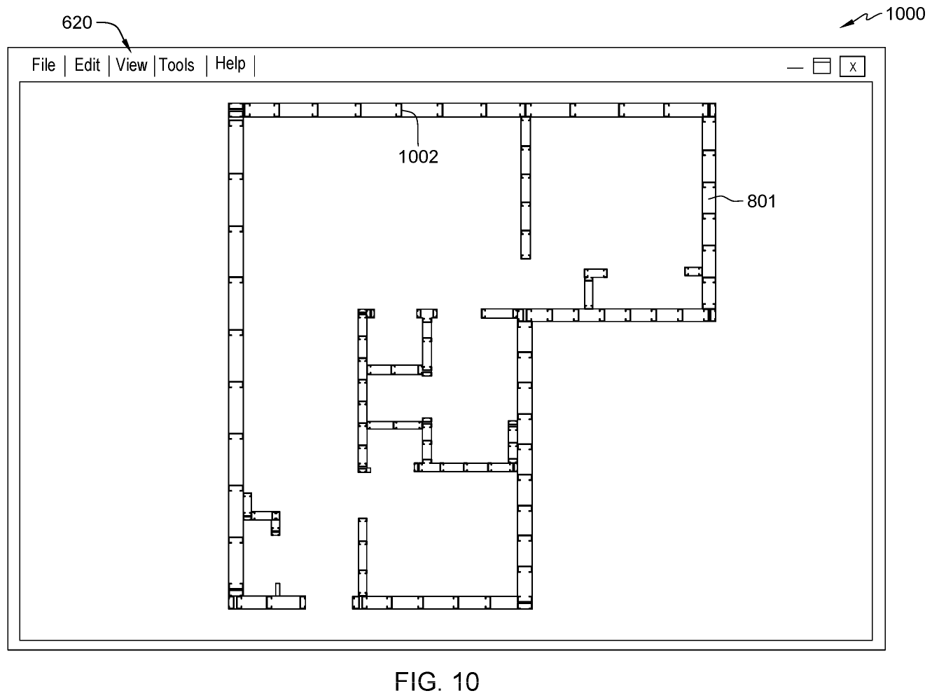

In step 410, the Centerline Program 108 generates the layout of the framing members for each wall segment based on the applied load(s). Based on the calculated load requirements for each wall segment, the Centerline Program 108 is able to determine the number and placement of framing members within the wall segment to meet the load requirements while also meeting the building requirements for the wall segment. As shown in FIG. 10, illustration 1000 shows wall frame layer 801 with the framing members layer 1002 overlayed. The framing member layer 1002 is based on the load analysis and is overlayed and centered on the wall framing layer 801 using the centerline layer 901 (hidden in this image). This includes end members, vertical members, horizontal members, framing members, and the like that are requirements to build the wall segment including all apertures, and the entire wall portions as well. As depicted in FIG. 6, illustration 600B, framing members 608 are shown positioned within the wall segments at predetermined locations based on the load analysis, and positioned based on the centerlines 603 and 606 and fit within the true wall interior dimensions. In Figure 700B the framing members 704 are shown again positioned based on the centerlines 703 and 707 and the framing members 704 are placed based on the load analysis, the interface of the wall segments, and the apertures of the wall segments. In the depicted illustration 700B the wall segment with centerline 703 is an interior wall and the wall segment with centerline 707 is an exterior wall. In the depicted embodiments, the centerlines, framing members, and architectural drawings are all overlayed, however within the user interface, the user can select which layers they want visible through the dropdown menus 620. In dropdown menus 620, “View” allows the user to select which layers are visible and invisible. So as new layers become available, the user is able to turn them on or off to get the view they desire. For example, FIGS. 6-10 show various drawings with different layers on and off. The layers can be framing members, center lines, architecture drawings, etc. In some embodiments, the completed centerline layers for all floors in the building are copied into a specified location. The Centerline Program 108 is able to start the importing of the layers and also add the relevant information about the particular floor. Through the various illustrations shown, the layers which are part of the illustrations which are generated may be customized by the user based on what they are looking for in the illustrations that are generated. These illustrations may also be generated for the creation of 3D models based on which layers are selected and how the Centerline Program 108 or a 3D modeling program would convert a drawing to a 3D model. A 3D model can be created of the framing member layout which is applied to the floor plans to create a building model. This newly created 3D model can be imported into various 3D modeling software to further create more complete 3D models that have, for example but not limited to, HVAC, plumbing, electrical, and other subsystems of the building model.

Using this datum or location recognition software, the Centerline Program 108 is able to correctly line up each floor plan if a 3D model is to be created from the drawings, this would include also the structural floor depth and height of the floor. In some embodiments, the Centerline Program 108 is able to import other information that was preserved in various other layers or data, such as details of the surfaces of the floor plan sheathing material properties, finishing material properties, insulation materials, height of the walls, placement of various objects within the floor plan (e.g. electrical, HVAC, mechanical), and the like.

In some embodiments, the Centerline Program 108 is able to take the centerline data and integrate that data with a datum for each floor in the building. Using the datums the Centerline Program 108 is able to correctly line up each floor plan, so that a 3D model can be created from the drawings. This would include the structural floor depth and height of the floors. In some embodiments, the Centerline Program 108 is able to import other information that was preserved in various other layers or data, such as details of the surfaces of the floor plan sheathing material properties, finishing material properties, insulation materials, height of the walls, placement of various objects within the floor plan (e.g. electrical, HVAC, mechanical), and the like to build a 3D model of the building where the newly calculated and integrated framing members are included in the 3D model, which previously were not know. Thus, creating a full 3D model of the building where the framing members are integrated into the model and can be interacted with.

The present invention provides the advantage of being to optimize the sheathing requirements for a building to calculate as close to exact of an answer of the quantity of sheathing and the alterations to the sheathing during install and also maximum the use and placement of the sheathing to reduce was and time lost.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein that are believed as maybe being new, this understanding, as indicated by use of the term “present invention,” is tentative and provisional and subject to change over the course of patent prosecution as relevant information is developed and as the claims are potentially amended.

The foregoing descriptions of various embodiments have been presented only for the purposes of illustration and description. They are not intended to be exhaustive or to limit the present invention to the forms disclosed. Accordingly, many modifications and variations of the present invention are possible in light of the above teachings will be apparent to practitioners skilled in the art. Additionally, the above disclosure is not intended to limit the present invention. In the specification and claims the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

Although various representative embodiments of this invention have been described above with a certain degree of particularity, those skilled in the art could make numerous alterations to the disclosed embodiments without departing from the spirit or scope of the inventive subject matter set forth in the specification and claims. Joinder references (e.g., attached, adhered, joined) are to be construed broadly and may include intermediate members between a connection of elements and relative movement between elements. As such, joinder references do not necessarily infer that two elements are directly connected and in fixed relation to each other. Moreover, network connection references are to be construed broadly and may include intermediate members or devices between network connections of elements. As such, network connection references do not necessarily infer that two elements are in direct communication with each other. In some instances, in methodologies directly or indirectly set forth herein, various steps and operations are described in one possible order of operation, but those skilled in the art will recognize that steps and operations may be rearranged, replaced or eliminated without necessarily departing from the spirit and scope of the present invention. It is intended that all matter contained in the above description or shown in the accompanying drawings shall be interpreted as illustrative only and not limiting. Changes in detail or structure may be made without departing from the spirit of the invention as defined in the appended claims.

Although the present invention has been described with reference to the embodiments outlined above, various alternatives, modifications, variations, improvements and/or substantial equivalents, whether known or that are or may be presently foreseen, may become apparent to those having at least ordinary skill in the art. Listing the steps of a method in a certain order does not constitute any limitation on the order of the steps of the method. Accordingly, the embodiments of the invention set forth above are intended to be illustrative, not limiting. A person skilled in the art will recognize that changes may be made in form and detail without departing from the spirit and scope of the invention. Therefore, the invention is intended to embrace all known or earlier developed alternatives, modifications, variations, improvements and/or substantial equivalents.

What is claimed is:

1. A computer method for calculating the centerline of a wall segment, comprising:
receiving, by one or more processors, an architectural drawing of floor plans of a building, wherein the floor plan includes interior and exterior walls with finishing materials;
identifying, by one or more processors, features of the floor plan, wherein the features are physical aspects of wall segments;
calculating, by one or more processors, the true width of the wall segments wherein the true width is that of framing members;
calculating, by one or more processors, a centerline of the wall segments based on the true width;
performing, by one or more processors, a load analysis, wherein a strength requirement for each wall segment is determined based on the building;
generating, by one or more processors, a layout of framing members for each of the wall segments based on the load analysis and the centerline of the wall segments;
generating, by one or more processors, layers of the framing member layout and the centerline layout of the floor plan.

2. The computer method of claim 1, wherein the identifying of the features of the floor plan, further comprising, removing, by one or more processors, features which are not associated with the wall segments.

3. The computer method of claim 1, wherein the identifying of the features of the floor plan, further comprising, tracing, by one or more processors, each feature of the floor plan to determine if the feature is associated with a wall segment.

4. The computer method of claim 1, further comprising, identifying, by one or more processors, apertures of the wall segments.

5. The computer method of claim 1, further comprising, processing, by on or more processors, the layers, so that the layers are correctly aligned based on the floor plans.

6. The computer method of claim 1, further comprising, providing, by one or more processors, options to allow the activation and deactivation of various layers through a user interface.

7. The computer method of claim 7, further comprising, generating, by one or more processors, a 3D model of the framing members.

8. A computer program product for generating a framing member layout,
the computer program product comprising a non-transitory computer readable storage medium having program instructions embodied therewith, the program instructions executable by a computing device to cause the computing device to:
program instructions to receive a set of floor plans that comprise a building model;
program instructions to identify features of the floor plan, wherein the features are the wall segments and apertures;
program instructions to isolate the wall segments of the floor plans, wherein a wall segment layer is created;
program instructions to calculate a true width of the wall segments, wherein the true width is that of framing members;
program instructions to calculate a centerline of the true width of the wall segments;
program instructions to generate a layer of the centerline;
program instructions to perform a load analysis on the floor plans while taking into consideration the building model to determine structural requirements for each wall segment;
program instructions to generate a framing member layout based on the structural requirements of the wall segments; and
program instructions to generate a layer of the framing member layout.

9. The computer program product of claim 8, wherein the identifying of the features of the floor plan, further comprising, program instructions to remove the features which are not associated with the walls and apertures.

10. The computer program product of claim 8, wherein framing member layout identifies interface between wall segments.

11. The computer program product of claim 8, further comprising, program instructions to identify the apertures, so that the apertures and the walls as distinguishable.

12. The computer program product of claim 8, wherein the calculation of the true width of the walls, further comprising, program instructions to identify the thickness of material beyond the true width of the wall segment and exclude the material beyond the true width of the wall segment in the calculation.

13. The computer program product of claim 8, wherein material properties are acquired for the load analysis.

14. The computer program product of claim 8, further comprising, program instructions to format the centerline layer from a first software language to a second software language.

15. A system comprising:
a CPU, a computer readable memory and a non-transitory computer readable storage medium associated with a computing device;
program instructions to receive a set of floor plans, wherein the set of floor plans comprise a building;
program instructions to identify wall segments of each of the set of floor plans and determine finishing materials which are part of the wall segment thickness;
program instructions to calculate a true width of the wall segments, wherein the true width is of the framing members excluding the finishing materials;
program instructions to generate a layer, wherein the layer is of a centerline of the true width of the wall segments;
program instructions to perform a load analysis on the building, wherein a strength requirement for each wall segment is calculated; and
program instructions to generate a layout of framing members for each wall segment.

16. The system of claim 15, further comprising, program instructions to determine a junction type between interfacing wall segments.

17. The system of claim 15, further comprising, program instructions to create a layer, wherein the layer is of the layout of the framing members for all of the wall segments.

18. The system of claim 16, wherein the layout of the framing members taking into account the junction type between interfacing wall segments.

19. The system of claim 15, further comprising, program instructions to generate a 3D model of the floor plans including the framing members.

20. The system of claim 15, further comprising, program instructions to identify apertures for the determination of the wall segments.
